(19) United States
(12) Patent Application Publication
(10) Pub. No.: US 2024/0365477 A1
(43) Pub. Date: Oct. 31, 2024

(54) CIRCUIT BOARD AND METHOD OF PRODUCING CIRCUIT BOARD

(71) Applicant: Murata Manufacturing Co., Ltd., Nagaokakyo-shi (JP)

(72) Inventors: Kosuke NISHIO, Nagaokakyo-shi (JP); Takayuki SHIMAMURA, Nagaokakyo-shi (JP)

(21) Appl. No.: 18/765,420

(22) Filed: Jul. 8, 2024

Related U.S. Application Data
(63) Continuation of application No. PCT/JP2023/006094, filed on Feb. 20, 2023.

(30) Foreign Application Priority Data
Mar. 7, 2022 (JP) 2022-034373

(51) Int. Cl. H05K 3/46; H05K 1/02

(52) U.S. Cl. CPC H05K 3/4605; H05K 1/0298; H05K 3/4652

(57) ABSTRACT

An interlayer connection conductor is inside a through-hole extending through first and second insulator layers in a Z-axis direction. A first conductor layer is on a negative main surface of an insulator layer farther in a negative direction of the Z-axis than the second insulator layer, and in contact with an end portion of the interlayer connection conductor in the negative direction of the Z-axis. A second conductor layer is on a positive main surface of the second insulator layer and in contact with an end portion of the interlayer connection conductor in a positive direction of the Z-axis. A surface roughness of a portion in the second insulator layer inside the through-hole is larger than a surface roughness of a portion in the first insulator layer inside the through-hole. No conductor layer in contact with the interlayer connection conductor is provided between the first and second insulator layers.

### CROSS REFERENCE TO RELATED APPLICATIONS

This application claims the benefit of priority to Japanese Patent Application No. 2022-034373 filed on Mar. 7, 2022 and is a Continuation Application of PCT Application No. PCT/JP2023/006094 filed on Feb. 20, 2023. The entire contents of each application are hereby incorporated herein by reference.

### BACKGROUND OF THE INVENTION

### 1. Field of the Invention

The present invention relates to circuit boards each having a structure in which a plurality of insulator layers are laminated.

### 2. Description of the Related Art

As an invention relating to a conventional circuit board, a resin substrate described in International Publication No. 2020/045402, for example, is known. Such a resin substrate includes a resin base material, interlayer connection conductors, and two conductors, wherein the resin base material has a structure in which a plurality of insulating base material layers are laminated in an up-down direction. The two conductors are provided on an upper main surface and a lower main surface of an insulator layer. The interlayer connection conductors pass through the insulator layer in the up-down direction. Thus, the interlayer connection conductors electrically connect the two conductors.

### SUMMARY OF THE INVENTION

In the resin n substrate described in International Publication No. 2020/045402, there is a desire to suppress the occurrence of connection failure between the interlayer connection conductors and the conductors.

Therefore, example embodiments of the present invention provide circuit boards each capable of reducing or preventing connection failure between interlayer connection conductors and conductor layers, and methods of producing such circuit boards.

A circuit board according to an example embodiment of the present invention includes a multilayer body including a plurality of insulator layers including a first insulator layer and a second insulator layer, the second insulator layer having a Young's modulus at room temperature higher than a Young's modulus at room temperature of the first insulator layer, the first and second insulator layers being laminated in a Z-axis direction, the plurality of insulator layers each including a negative main surface located in a negative direction of a Z-axis and a positive main surface located in a positive direction of the Z-axis, the negative main surface of the second insulator layer being in contact with the positive main surface of the first insulator layer, an interlayer connection conductor provided inside a through-hole that passes through the first insulator layer and the second insulator layer in the Z-axis direction, a first conductor layer that is located on the negative main surface of the insulator layer located farther in the negative direction of the Z-axis than the second insulator layer, and that is in contact with an end portion of the interlayer connection conductor in the negative direction of the Z-axis, and a second conductor layer that is located on the positive main surface of the second insulator layer and that is in contact with an end portion of the interlayer connection conductor in the positive direction of the Z-axis, wherein a surface roughness of a portion located in the second insulator layer within an inner peripheral surface of the through-hole is larger than a surface roughness of a portion located in the first insulator layer within the inner peripheral surface of the through-hole, and no conductor layer in contact with the interlayer connection conductor is provided between the first insulator layer and the second insulator layer.

A method of producing a circuit board according to an example embodiment of the present invention includes preparing a first insulator layer and a second insulator layer each including a negative main surface located in a negative direction of a Z-axis and a positive main surface located in a positive direction of the Z-axis, the second insulator layer having a Young's modulus at room temperature higher than a Young's modulus at room temperature of the first insulator layer, a second conductor layer being provided on the positive main surface of the second insulator layer, after the preparing, laminating the first insulator layer and the second insulator layer so that the negative main surface of the second insulator layer in the Z-axis is in contact with the positive main surface of the first insulator layer, after the laminating, radiating a laser beam from a space located in the negative direction of the first insulator layer and the second insulator layer to form a through-hole that passes through the first insulator layer and the second insulator layer in a Z-axis direction, and after the radiating, forming an interlayer connection conductor inside the through-hole, wherein in the radiating, the laser beam is radiated while an intensity of the laser beam is increased over time.

With the circuit boards and the methods of producing the circuit boards according to example embodiments of the present invention, connection failure between the interlayer connection conductors and the conductor layers can be reduced or prevented.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is an exploded perspective view of a circuit board 10.

FIG. 2 is a cross-sectional view of a right-end portion of the circuit board 10.

FIG. 3 is a back view of an electronic device 1 that includes the circuit board 10.

FIG. 4 is a cross-sectional view of the circuit board 10 during production.

FIG. 5 is a cross-sectional view of the circuit board 10 during production.

FIG. 6 is a cross-sectional view of the circuit board 10 during production.

FIG. 7 is a cross-sectional view of the circuit board 10 during production.

FIG. 8 is a cross-sectional view of the circuit board 10 during production.

FIG. 9 is a cross-sectional view of a right-end portion of a circuit board 10a.

FIG. 10 is a cross-sectional view of a right-end portion of a circuit board 10b.

FIG. 11 is a cross-sectional view of a right-end portion of a circuit board 10c.

FIG. 12 is a cross-sectional view of a right-end portion of a circuit board 10d.

FIG. 13 is a cross-sectional view of a right-end portion of a circuit board 10e.

### DETAILED DESCRIPTION OF THE EXAMPLE EMBODIMENTS

### Example Embodiments

### Structure of Circuit Board

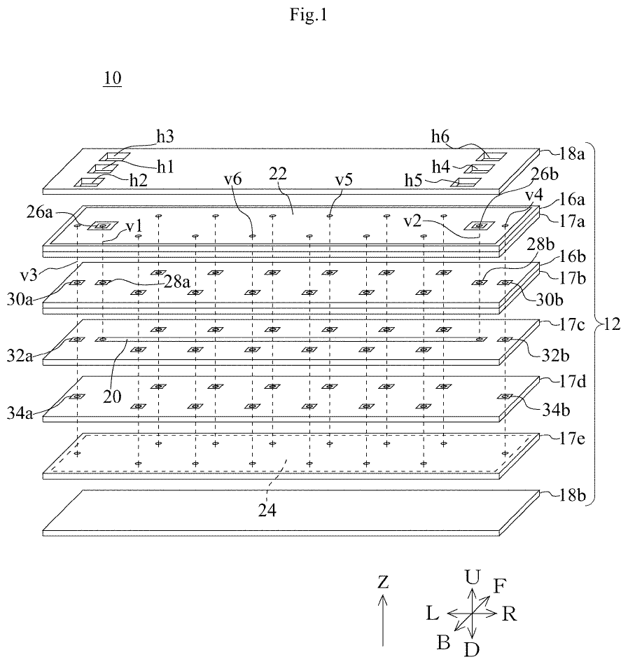

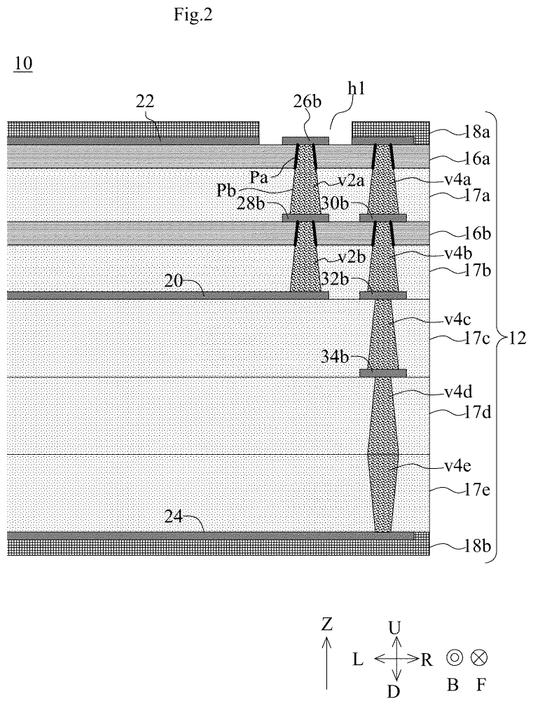

The structure of a circuit board 10 according to an example embodiment of the present invention will be described below with reference to the drawings. FIG. 1 is an exploded perspective view of the circuit board 10. FIG. 2 is a cross-sectional view of a right-end portion of the circuit board 10. FIG. 2 shows a cross section orthogonal to a front-back direction.

In the present description, direction is defined as follows. The laminating direction of a multilayer body 12 of the circuit board 10 is defined as an up-down direction. The up-down direction coincides with the Z-axis direction. The up direction is the positive direction of the Z-axis. The down direction is the negative direction of the Z-axis. The direction in which a signal conductor layer 20 of the circuit board 10 extends is defined as a left-right direction. The line width direction of the signal conductor layer 20 when viewed in the up-down direction is defined as a front-back direction. The up-down direction, the front-back direction, and the left-right direction are orthogonal to each other. Note that the up direction and the down direction of the up-down direction may be interchanged, the left direction and the right direction of the left-right direction may be interchanged, and the front direction and the back direction of the front-back direction may be interchanged.

Hereinafter, X is a component or portion of the circuit board 10. In the present description, unless otherwise noted, each portion of X is defined as follows. A front portion of X means the front half of X. A back portion of X means the back half of X. A left portion of X means the left half of X. A right portion of X means the right half of X. An upper portion of X means the upper half of X. A lower portion of X means the lower half of X. A front end of X means an end of X in the front direction. A back end of X means an end of X in the back direction. A left end of X means an end of X in the left direction. A right end of X means an end of X in the right direction. An upper end of X means an end of X in the up direction. A lower end of X means an end of X in the down direction. A front-end portion of X means the front end of X and its vicinity. A back-end portion of X means the back end of X and its vicinity. A left-end portion of X means the left end of X and its vicinity. A right-end portion of X means the right end of X and its vicinity. An upper-end portion of X means the upper end of X and its vicinity. A lower-end portion of X means the lower end of X and its vicinity.

First, the structure of the circuit board 10 is described with reference to FIG. 1. The circuit board 10 transmits a high-frequency signal. The circuit board 10 is used to electrically connect two circuits in an electronic device such as a smartphone. As shown in FIG. 1, the circuit board 10 includes a multilayer body 12, a signal conductor layer 20, a first ground conductor layer 22, a second ground conductor layer 24, signal terminals 26a and 26b, connection conductor layers 28a, 28b, 30a, 30b, 32a, 32b, 34a, and 34b, interlayer connection conductors v1 to v4 and a plurality of interlayer connection conductors v5 and v6.

The multilayer body 12 has a plate shape. Therefore, the multilayer body 12 includes an upper main surface and a lower main surface. The upper main surface and the lower main surface of the multilayer body 12 have a rectangular or substantially rectangular shape with the long sides extending in the left-right direction. Thus, the length of the multilayer body 12 in the left-right direction is longer than the length of the multilayer body 12 in the front-back direction. The multilayer body 12 is flexible.

As shown in FIG. 1, the multilayer body 12 has a structure in which insulator layers 16a, 16b, 17a to 17e, 18a, and 18b are laminated in the up-down direction (the Z-axis direction). The insulator layers 18a, 16a, 17a, 16b, 17b to 17e, and 18b are laminated in this order from top to bottom. The insulator layers 16a, 16b, 17a to 17e, 18a, and 18b each have a lower main surface (negative main surface located in the negative direction of the Z-axis) and an upper main surface (positive main surface located in the positive direction of the Z-axis). The lower main surface (negative main surface) of the insulator layer 16a (second insulator layer) is in contact with the upper main surface (positive main surface) of the insulator layer 17a (first insulator layer). The lower main surface (negative main surface) of the insulator layer 16b (second insulator layer) is in contact with the upper main surface (positive main surface) of the insulator layer 17b (first insulator layer).

When viewed in the up-down direction, the insulator layers 16a, 16b, 17a to 17e, 18a, and 18b have the same rectangular or substantially rectangular shape as the multilayer body 12. The insulator layers 16a, 16b, and 17a to 17e are dielectric sheets having flexibility. The materials of the insulator layers 16a, 16b, and 17a to 17e are, for example, thermoplastic resin. However, the insulator layers 16a and 16b (second insulator layers) have a Young's modulus at room temperature higher than the Young's modulus at room temperature of the insulator layers 17a to 17e (first insulator layers). The material of the insulator layers 16a and 16b is, for example, fluororesin. The material of the insulator layers 17a to 17e is, for example, liquid crystal polymer. The thickness of the insulator layers 16a and 16b (second insulator layers) in the up-down direction (the Z-axis direction) is smaller than the thickness of the insulator layers 17a and 17b (first insulator layers) in the up-down direction (the Z-axis direction). In the present description, the thickness of the insulator layer in the up-down direction is, for example, an average value of the overall thickness of the insulator layer in the up-down direction. The insulator layers 18a and 18b will be described later.

The signal conductor layer 20 is provided in the multilayer body 12, as shown in FIG. 1. In the present example embodiment, the signal conductor layer 20 is located on the upper main surface of the insulator layer 17c. In other words, the signal conductor layer 20 (second conductor layer) is located on the lower main surface (negative main surface) of the insulator layer 17b (first insulator layer), which is located below (in the negative direction of the Z-axis) the insulator layer 16b (second insulator layer). The signal conductor layer 20 has a linear shape. The signal conductor layer 20 extends in the left-right direction. The high-frequency signal is transmitted in the signal conductor layer 20.

The first ground conductor layer 22 is provided in the multilayer body 12, as shown in FIG. 1. The first ground conductor layer 22 is provided above the signal conductor layer 20 so that it overlaps the signal conductor layer 20 when viewed in the up-down direction. In the present example embodiment, the first ground conductor layer 22 (second conductor layer) is located on the upper main surface (positive main surface) of the insulator layer 16a (second insulator layer). The first ground conductor layer 22 covers substantially the entire upper main surface of the insulator layer 16a. The ground potential is connected to the first ground conductor layer 22.

The second ground conductor layer 24 is provided in the multilayer body 12, as shown in FIG. 1. The second ground conductor layer 24 is provided below the signal conductor layer 20 so that it overlaps the signal conductor layer 20 when viewed in the up-down direction. In the present example embodiment, the second ground conductor layer 24 is located on the lower main surface of the insulator layer 17e. The second ground conductor layer 24 covers substantially the entire lower main surface of the insulator layer 17e. The ground potential is connected to the second ground conductor layer 24. The signal conductor layer 20, first ground conductor layer 22, and second ground conductor layer 24 described above have a stripline structure.

The signal terminal 26b is provided at the right-end portion of the multilayer body 12. More specifically, the signal terminal 26b (second conductor layer) is located on the upper main surface (positive main surface) of the insulator layer 16a (second insulator layer). When viewed in the up-down direction, the signal terminal 26b overlaps the right-end portion of the signal conductor layer 20. When viewed in the up-down direction, the signal terminal 26b has a rectangular or substantially rectangular shape. The signal terminal 26b is an external terminal where high-frequency signals are input and output. The signal terminal 26b is not in contact with the first ground conductor layer 22.

The connection conductor layer 28b is provided at the right-end portion of the multilayer body 12. More specifically, the connection conductor layer 28b (second conductor layer) is located on the upper main surface (positive main surface) of the insulator layer 16b (second insulator layer). In other words, the connection conductor layer 28b (first conductor layer) is located on the lower main surface (negative main surface) of the insulator layer 17a (first insulator layer), which is located below (in the negative direction of the Z-axis) the insulator layer 16a (second insulator layer). The connection conductor layer 28b functions as a first conductor layer for an interlayer connection conductor v2a and as a second conductor layer for an interlayer connection conductor v2b. When viewed in the up-down direction, the connection conductor layer 28b overlaps the right-end portion of the signal conductor layer 20. When viewed in the up-down direction, the connection conductor layer 28b has a rectangular or substantially rectangular shape.

The connection conductor layer 30b is provided at the right-end portion of the multilayer body 12. More specifically, the connection conductor layer 30b (second conductor layer) is located on the upper main surface (positive main surface) of the insulator layer 16b (second insulator layer). The connection conductor layer 30b is located to the right of the connection conductor layer 28b. In other words, the connection conductor layer 30b (first conductor layer) is located on the lower main surface (negative main surface) of the insulator layer 17a (first insulator layer), which is located below (in the negative direction of the Z-axis) the insulator layer 16a (second insulator layer). When viewed in the up-down direction, the connection conductor layer 30b overlaps the first ground conductor layer 22 and the second ground conductor layer 24. When viewed in the up-down direction, the connection conductor layer 30b has a rectangular or substantially rectangular shape.

The connection conductor layer 32b is provided at the right-end portion of the multilayer body 12. More specifically, the connection conductor layer 32b (second conductor layer) is located on the upper main surface of the insulator layer 17c. In other words, the connection conductor layer 32b (first conductor layer) is located on the lower main surface (negative main surface) of the insulator layer 17b (first insulator layer), which is located below (in the negative direction of the Z-axis) the insulator layer 16b (second insulator layer). When viewed in the up-down direction, the connection conductor layer 32b overlaps the first ground conductor layer 22 and the second ground conductor layer 24. When viewed in the up-down direction, the connection conductor layer 32b has a rectangular or substantially rectangular shape.

The connection conductor layer 34b is provided at the right-end portion of the multilayer body 12. More specifically, the connection conductor layer 34b is located on the upper main surface of the insulator layer 17d. When viewed in the up-down direction, the connection conductor layer 34b overlaps the first ground conductor layer 22 and the second ground conductor layer 24. When viewed in the up-down direction, the connection conductor layer 34b has a rectangular or substantially rectangular shape.

The interlayer connection conductor v2 electrically connects the signal terminal 26b, the connection conductor layer 28b, and the right-end portion of the signal conductor layer 20. More specifically, the interlayer connection conductor v2 includes interlayer connection conductors v2a and v2b. The interlayer connection conductor v2a is provided inside a through-hole that passes through the insulator layer 16a (second insulator layer) and the insulator layer 17a (first insulator layer) in the up-down direction (the Z-axis direction). Thus, the signal terminal 26b (second conductor layer) is in contact with the upper-end portion (the end portion in the positive direction of the Z-axis) of the interlayer connection conductor v2a. The connection conductor layer 28b (first conductor layer) is in contact with the lower-end portion (the end portion in the negative direction of the Z-axis) of the interlayer connection conductor v2a. However, the interlayer connection conductor v2a does not pass through the connection conductor layer 28b (first conductor layer) and the signal terminal 26b (second conductor layer) in the up-down direction (the Z-axis direction).

The interlayer connection conductor v2a has a truncated cone shape. When viewed in the up-down direction (the Z-axis direction), the area of the upper end of the interlayer connection conductor v2a (the end in the positive direction of the Z-axis) is smaller than the area of the lower end of the interlayer connection conductor v2a (the end in the negative direction of the Z-axis). The surface roughness of a portion Pa located in the insulator layer 16a (second insulator layer) within the inner peripheral surface of the through-hole is larger than the surface roughness of a portion Pb located in the insulator layer 17a (first insulator layer) within the inner peripheral surface of the through-hole.

The interlayer connection conductor v2b is provided inside a through-hole that passes through the insulator layer 16b (second insulator layer) and the insulator layer 17b (first insulator layer) in the up-down direction (the Z-axis direction). Thus, the connection conductor layer 28b (second conductor layer) is in contact with the upper-end portion (the end portion in the positive direction of the Z-axis) of the interlayer connection conductor v2b. The right-end portion of the signal conductor layer 20 (first conductor layer) is in contact with the lower-end portion (the end portion in the negative direction of the Z-axis) of the interlayer connection conductor v2b. However, the interlayer connection conductor v2b does not pass through the signal conductor layer 20 (first conductor layer) and the connection conductor layer 28b (second conductor layer) in the up-down direction (the Z-axis direction).

The interlayer connection conductor v2b has a truncated cone shape. When viewed in the up-down direction (the Z-axis direction), the area of the upper end of the interlayer connection conductor v2b (the end in the positive direction of the Z-axis) is smaller than the area of the lower end of the interlayer connection conductor v2b (the end in the negative direction of the Z-axis). The surface roughness of a portion Pa located in the insulator layer 16b (second insulator layer) within the inner peripheral surface of the through-hole is larger than the surface roughness of a portion Pb located in the insulator layer 17b (first insulator layer) within the inner peripheral surface of the through-hole.

The interlayer connection conductor v4 electrically connects the first ground conductor layer 22, the connection conductor layer 30b, the connection conductor layer 32b, the connection conductor layer 34b, and the second ground conductor layer 24. More specifically, the interlayer connection conductor v4 includes interlayer connection conductors v4a, v4b, v4c, v4d, and v4e. The interlayer connection conductor v4a is provided inside a through-hole that passes through the insulator layer 16a (second insulator layer) and the insulator layer 17a (first insulator layer) in the up-down direction (the Z-axis direction). Thus, the first ground conductor layer 22 (second conductor layer) is in contact with the upper-end portion (the end portion in the positive direction of the Z-axis) of the interlayer connection conductor v4a. The connection conductor layer 30b (first conductor layer) is in contact with the lower-end portion (the end portion in the negative direction of the Z-axis) of the interlayer connection conductor v4a. However, the interlayer connection conductor v4a does not pass through the connection conductor layer 30b (first conductor layer) and the first ground conductor layer 22 (second conductor layer) in the up-down direction (the Z-axis direction).

The interlayer connection conductor v4a has a truncated cone shape. When viewed in the up-down direction (the Z-axis direction), the area of the upper end of the interlayer connection conductor v4a (the end in the positive direction of the Z-axis) is smaller than the area of the lower end of the interlayer connection conductor v4a (the end in the negative direction of the Z-axis). The surface roughness of a portion Pa located in the insulator layer 16a (second insulator layer) within the inner peripheral surface of the through-hole is larger than the surface roughness of a portion Pb located in the insulator layer 17a (first insulator layer) within the inner peripheral surface of the through-hole.

The interlayer connection conductor v4b is provided inside a through-hole that passes through the insulator layer 16b (second insulator layer) and the insulator layer 17b (first insulator layer) in the up-down direction (the Z-axis direction). Thus, the connection conductor layer 30b (second conductor layer) is in contact with the upper-end portion (the end portion in the positive direction of the Z-axis) of the interlayer connection conductor v4b. The connection conductor layer 32b (first conductor layer) is in contact with the lower-end portion (the end portion in the negative direction of the Z-axis) of the interlayer connection conductor v4b. However, the interlayer connection conductor v4b does not pass through the connection conductor layer 32b (first conductor layer) and the connection conductor layer 30b (second conductor layer) in the up-down direction (the Z-axis direction).

The interlayer connection conductor v4b has a truncated cone shape. When viewed in the up-down direction (the Z-axis direction), the area of the upper end of the interlayer connection conductor v4b (the end in the positive direction of the Z-axis) is smaller than the area of the lower end of the interlayer connection conductor v4b (the end in the negative direction of the Z-axis). The surface roughness of a portion Pa located in the insulator layer 16b (second insulator layer) within the inner peripheral surface of the through-hole is larger than the surface roughness of a portion Pb located in the insulator layer 17b (first insulator layer) within the inner peripheral surface of the through-hole.

The interlayer connection conductor v4c is provided inside a through-hole that passes through the insulator layer 17c in the up-down direction. Thus, the connection conductor layer 32b is in contact with the upper-end portion of the interlayer connection conductor v4c. The connection conductor layer 34b is in contact with the lower-end portion of the interlayer connection conductor v4c. However, the interlayer connection conductor v4c does not pass through the connection conductor layer 34b and the connection conductor layer 32b in the up-down direction. The interlayer connection conductor v4c has a truncated cone shape. When viewed in the up-down direction, the area of the upper end of the interlayer connection conductor v4c is smaller than the area of the lower end of the interlayer connection conductor v4c.

Each of the interlayer connection conductors v4d and v4e is provided inside a through-hole that passes through the insulator layers 17d and 17e in the up-down direction. The interlayer connection conductor v4d and the interlayer connection conductor v4e are connected so that they are aligned in the up-down direction. Thus, the connection conductor layer 34b is in contact with the upper-end portion of the interlayer connection conductor v4d. The second ground conductor layer 24 is in contact with the lower-end portion of the interlayer connection conductor v4e. However, the interlayer connection conductor v4d does not pass through the connection conductor layer 34b in the up-down direction. The interlayer connection conductor v4e does not pass through the second ground conductor layer 24 in the up-down direction. The interlayer connection conductors v4d and v4e each have a truncated cone shape. When viewed in the up-down direction, the area of the upper end of the interlayer connection conductor v4d is smaller than the area of the lower end of the interlayer connection conductor v4d. When viewed in the up-down direction, the area of the lower end of the interlayer connection conductor v4e is smaller than the area of the upper end of the interlayer connection conductor v4e. The position of the lower end of the interlayer connection conductor v4d in the up-down direction and the position of the upper end of the interlayer connection conductor v4e in the up-down direction coincide with the position of the lower main surface of the insulator layer 17d in the up-down direction and the position of the upper main surface of the insulator layer 17e in the up-down direction.

No conductor layer in contact with the interlayer connection conductors v2a and v4a is provided between the insulator layer 17a (first insulator layer) and the insulator layer 16a (second insulator layer). In the present example embodiment, no conductor layer is provided between the insulator layer 17a (first insulator layer) and the insulator layer 16a (second insulator layer). Similarly, no conductor layer in contact with the interlayer connection conductors v2b and v4b is provided between the insulator layer 17b (first insulator layer) and the insulator layer 16b (second insulator layer). In the present example embodiment, no conductor layer is provided between the insulator layer 17b (first insulator layer) and the insulator layer 16b (second insulator layer).

The plurality of interlayer connection conductors v5 are located in front of the signal conductor layer 20. The plurality of interlayer connection conductors v5 are aligned in a row in the left-right direction. The plurality of interlayer connection conductors v5 electrically connect the first ground conductor layer 22 and the second ground conductor layer 24. However, since the structure of the plurality of interlayer connection conductors v5 is the same as that of the interlayer connection conductor v4, the description thereof will be omitted.

The plurality of interlayer connection conductors v6 are located after the signal conductor layer 20. The plurality of interlayer connection conductors v6 are aligned in a row in the left-right direction. The plurality of interlayer connection conductors v6 electrically connect the first ground conductor layer 22 and the second ground conductor layer 24. However, since the structure of the plurality of interlayer connection conductors v6 is the same as that of the interlayer connection conductor v4, the description thereof will be omitted.

The insulator layers 18a and 18b are protective layers having flexibility. When viewed in the up-down direction, the insulator layers 18a and 18b have the same rectangular or substantially rectangular shape as the multilayer body 12.

The insulator layer 18a covers substantially the entire upper main surface of the insulator layer 16a. Thus, the insulator layer 18a protects the first ground conductor layer 22. However, openings h1 to h6 are provided in the insulator layer 18a. When viewed in the up-down direction, the opening h4 overlaps the signal terminal 26b. Thus, the signal terminal 26b is exposed to the outside from the circuit board 10 via the opening h4. The opening h5 is provided behind the opening h4. When viewed in the up-down direction, the opening h5 overlaps the first ground conductor layer 22. Thus, a portion of the first ground conductor layer 22 is exposed to the outside from the circuit board 10 via the opening h5. A portion of the first ground conductor layer 22 serves as a ground terminal. The opening h6 is provided in front of the opening h4. When viewed in the up-down direction, the opening h6 overlaps the first ground conductor layer 22. Thus, a portion of the first ground conductor layer 22 is exposed to the outside from the circuit board 10 via the opening h6. A portion of the first ground conductor layer 22 serves as a ground terminal.

The insulator layer 18b covers substantially the entire lower main surface of the insulator layer 17e. Thus, the insulator layer 18b covers the second ground conductor layer 24.

The structure of the right-end portion of the circuit board 10 has been described above. The structure of the left-end portion of the circuit board 10 has a left-right symmetrical relationship with the structure of the right-end portion of the circuit board 10. Therefore, the description for the structure of the left-end portion of the circuit board 10 is omitted.

The first ground conductor layer 22, second ground conductor layer 24, signal terminals 26a and 26b, and connection conductor layers 28a, 28b, 30a, 30b, 32a, 32b, 34a, and 34b described above are formed, for example, by etching a metal foil provided on the upper main surface or the lower main surface of the insulator layers 16a, 16b, and 17a to 17e. The metal foil is, for example, a copper foil.

The surface roughness of the lower main surfaces (negative main surfaces) of the first ground conductor layer 22, second ground conductor layer 24, signal terminals 26a and 26b, and connection conductor layers 28a, 28b, 30a, 30b, 32a, 32b, 34a, and 34b (first conductor layer and second conductor layer) is equal or substantially equal to the surface roughness of the upper main surfaces (positive main surfaces) of the first ground conductor layer 22, second ground conductor layer 24, signal terminals 26a and 26b, and connection conductor layers 28a, 28b, 30a, 30b, 32a, 32b, 34a, and 34b (first conductor layer and second conductor layer). However, the copper foil is chemically bonded to the fluororesin. Therefore, the first ground conductor layer 22 and the signal terminals 26a and 26b are firmly fixed to the insulator layer 16a. The connection conductor layers 28a, 28b, 30a, and 30b are firmly fixed to the insulator layer 16b.

The interlayer connection conductors v1 to v6 are, for example, via-hole conductors. The via-hole conductors are made by forming through-holes in the insulator layers 16a, 16b, and 17a to 17e, filling the through-holes with a conductive paste, and sintering the conductive paste. The conductive paste is a mixture of metal powder and a resin.

### Structure of Electronic Device

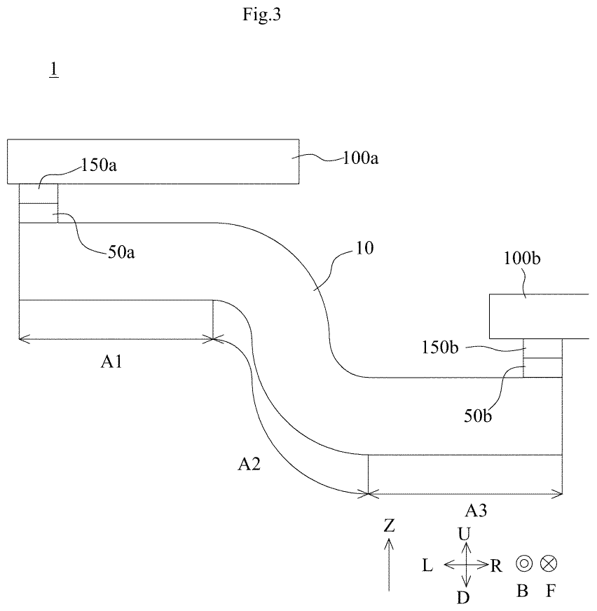

Next, the structure of an electronic device 1 that includes the circuit board 10 will be described with reference to the drawings. FIG. 3 is a back view of the electronic device 1 that includes the circuit board 10. The electronic device 1 is, for example, a portable wireless communication terminal. The electronic device 1 is, for example, a smartphone.

The circuit board 10 is used with the multilayer body 12 bent as shown in FIG. 3. The term “with the multilayer body 12 bent” means that the multilayer body 12 is deformed and bent by an external force applied to the multilayer body 12. The deformation may be elastic, plastic, or elastic and plastic deformation.

The multilayer body 12 includes a first section A1, a second section A2, and a third section A3. The first section A1, the second section A2, and the third section A3 are aligned in this order from left to right. The first section A1 and the third section A3 are not bent. The second section A2 bends, relative to the first section A1, to the down direction (the Z-axis direction) of the first section A1. However, the first section A1 and the third section A3 may also be slightly bent. In such a case, the radius of curvature of the first section A1 and the third section A3 are larger than the radius of curvature of the second section A2.

The electronic device 1 includes the circuit board 10, connectors 50a, 50b, 150a, and 150b, and circuit boards 100a and 100b. The connector 50a is mounted on the left-end portion of the upper main surface of the circuit board 10. The connector 150b is mounted on the right-end portion of the upper main surface of the circuit board 10.

The connector 150a is mounted on the lower main surface of the circuit board 100a. The connector 150a is connected to the connector 50a. The connector 150b is mounted on the lower main surface of the circuit board 100b. The connector 150b is connected to the connector 50b. Thus, the circuit board 10 electrically connects the circuit board 100a and the circuit board 100b.

### Method of Producing Circuit Board 10

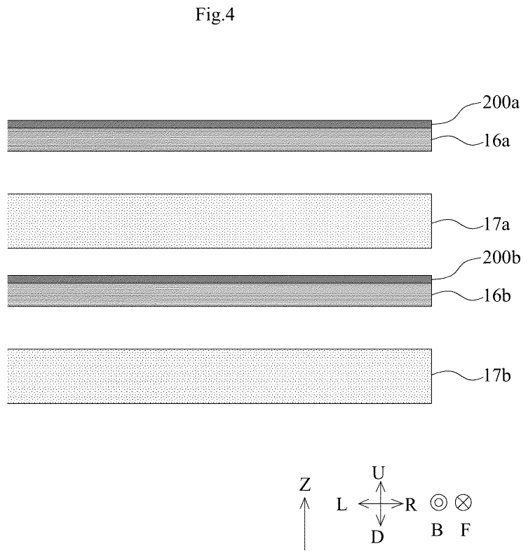

Next, a method of producing the circuit board 10 will be described with reference to the drawings. FIGS. 4 to 8 are cross-sectional views of the circuit board 10 during production.

As shown in FIG. 4, the insulator layers 17a and 17b (first insulator layers) and the insulator layers 16a and 16b (second insulator layers) having a lower main surface (the negative main surface located in the negative direction of the Z-axis) and an upper main surface (the positive main surface located in the positive direction of the Z-axis) are prepared (preparation step). The insulator layers 16a and 16b (second insulator layers) have a Young's modulus at room temperature higher than the Young's modulus at room temperature of the insulator layers 17a and 17b (first insulator layers). In the present description, room temperature is defined as about 5° C. or higher and about 35° C. or lower, for example. A conductor layer 200a (second conductor layer) is provided on the upper main surface (positive main surface) of the insulator layer 16a (second insulator layer). A conductor layer 200b (second conductor layer) is provided on the upper main surface (positive main surface) of the insulator layer 16b (second insulator layer).

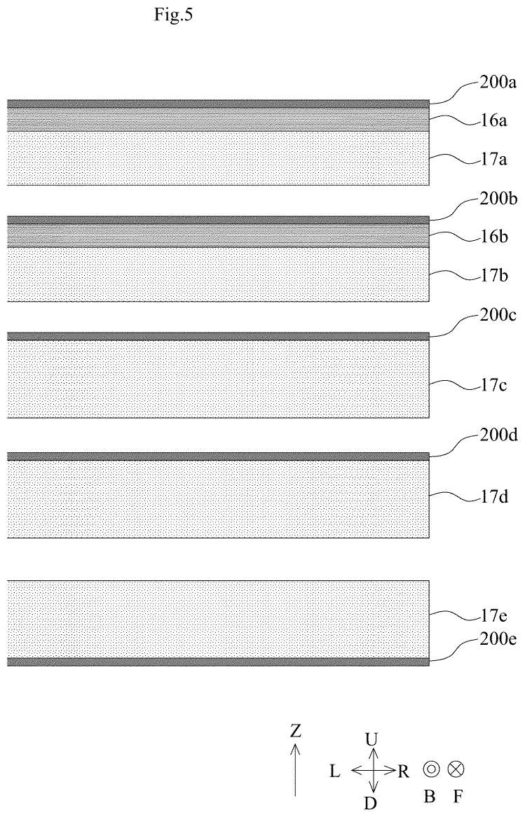

Further, as shown in FIG. 5, the insulator layers 17c to 17e are prepared. A conductor layer 200c is provided on the upper main surface of the insulator layer 17c. A conductor layer 200d is provided on the upper main surface of the insulator layer 17d. A conductor layer 200e is provided on the upper main surface of the insulator layer 17e.

After the preparation step, as shown in FIG. 5, the insulator layer 17a (first insulator layer) and the insulator layer 16a (second insulator layer) are laminated (lamination step) so that the lower main surface (negative main surface) of the insulator layer 16a (second insulator layer) contacts the upper main surface (positive main surface) of the insulator layer 17a (first insulator layer). At this time, the insulator layer 17a and the insulator layer 16a are thermally pressure bonded by applying heat treatment and pressure treatment to the insulator layer 17a and the insulator layer 16a. Similarly, the insulator layer 17b (first insulator layer) and the insulator layer 16b (second insulator layer) are laminated (lamination step) so that the lower main surface (negative main surface) of the insulator layer 16b (second insulator layer) contacts the upper main surface (positive main surface) of the insulator layer 17b (first insulator layer). At this time, the insulator layer 17b and the insulator layer 16b are thermally pressure bonded by applying heat treatment and pressure treatment to the insulator layer 17b and the insulator layer 16b.

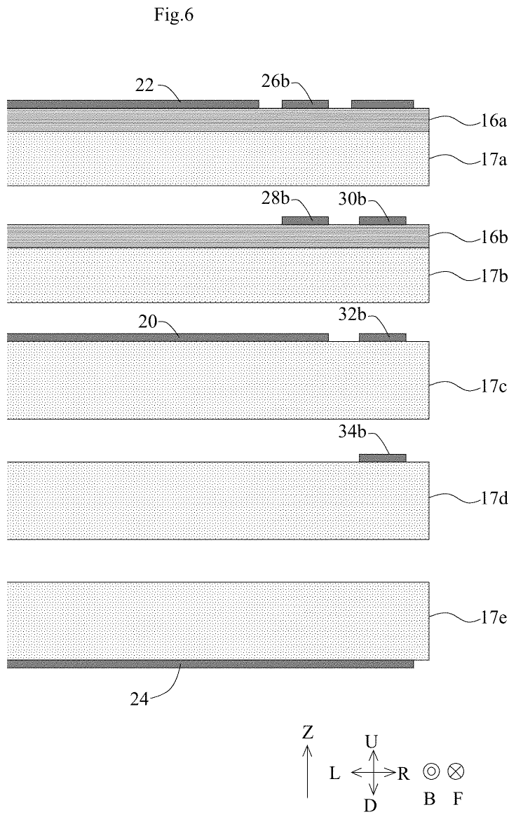

After the lamination step, as shown in FIG. 6, the conductor layers 200a to 200e are patterned by performing a photolithography step (patterning step). As a result, the first ground conductor layer 22, the second ground conductor layer 24, the signal terminals 26a and 26b, and the connection conductor layers 28a, 28b, 30a, 30b, 32a, 32b, 34a, and 34b are formed.

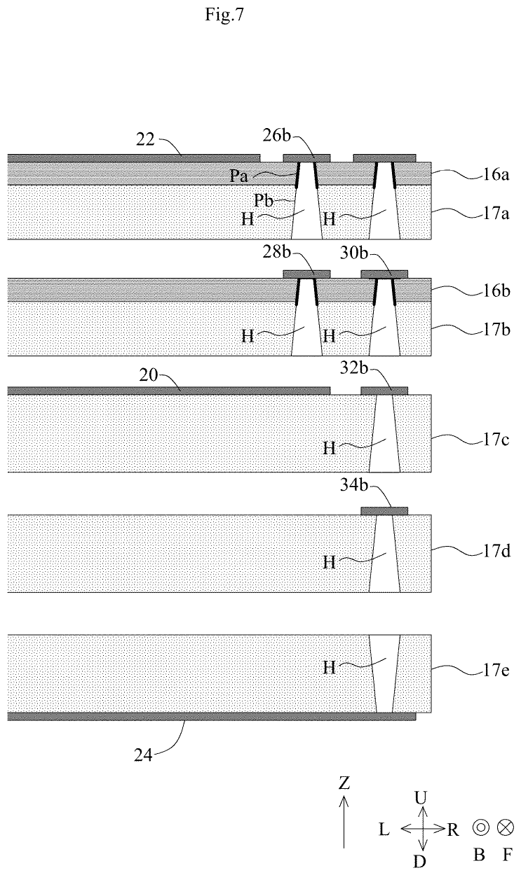

After the patterning step, as shown in FIG. 7, a laser beam is radiated from a space located below (in the negative direction of the Z-axis) the insulator layer 17a (first insulator layer) and the insulator layer 16a (second insulator layer) to form a through-hole H that passes through the insulator layer 17a (first insulator layer) and the insulator layer 16a (second insulator layer) in the up-down direction (the Z-axis direction) (through-hole forming step). In the through-hole forming step, the laser beam is radiated so that the through-hole H does not pass through the conductor layer 200a (second conductor layer) in the up-down direction (the Z-axis direction). Similarly, a laser beam is radiated from a space located below (in the negative direction of the Z-axis) the insulator layer 17b (first insulator layer) and the insulator layer 16b (second insulator layer) to form a through-hole H that passes through the insulator layer 17b (first insulator layer) and the insulator layer 16b (second insulator layer) in the up-down direction (the Z-axis direction) (through-hole forming step). In the through-hole forming step, the laser beam is radiated so that the through-hole H does not pass through the conductor layer 200b (second conductor layer) in the up-down direction (the Z-axis direction). The insulator layers 17c to 17e are also irradiated with a laser beam to form a through-hole H.

Here, in the through-hole forming step, the laser beam is radiated while the intensity of the laser beam is increased over time. The increase of the intensity of the laser beam can be done continuously or in a stepwise manner. As a result, the surface roughness of the portion Pa located in the insulator layer 16a (second insulator layer) within the inner peripheral surface of the through-hole is larger than the surface roughness of the portion Pb located in the insulator layer 17a (first insulator layer) within the inner peripheral surface of the through-hole. Similarly, the surface roughness of the portion Pa located in the insulator layer 16b (second insulator layer) within the inner peripheral surface of the through-hole is larger than the surface roughness of the portion Pb located in the insulator layer 17b (first insulator layer) within the inner peripheral surface of the through-hole.

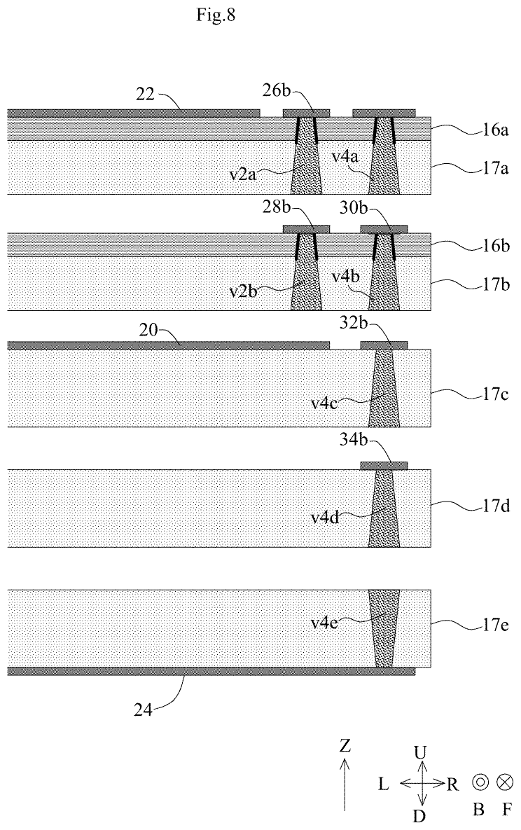

After the through-hole forming step, as shown in FIG. 8, the interlayer connection conductors v1 to v6 are formed inside the through-holes H (interlayer connection conductor forming step). In the interlayer connection conductor forming step, the through-holes H are filled with a conductive paste.

After the through-hole forming step, as shown in FIG. 2, the insulator layers 16a, 16b, 17a to 17e, 18a, and 18b including the insulator layers 17a and 17b (first insulator layer) and the insulator layers 16a and 16b (second insulator layer) are laminated (second lamination step). In the second lamination step, the insulator layers 16a, 16b, 17a to 17e, 18a, and 18b are thermally pressure bonded by applying heat treatment and pressure treatment to the insulator layers 16a, 16b, 17a to 17e, 18a, and 18b. By the heat treatment, the insulator layers 16a, 16b, 17a to 17e, 18a, and 18b are fused, and the conductive paste in the through-holes H is solidified. After the above steps, the circuit board 10 is completed.

### Advantageous Effects

With the circuit board 10, the occurrence of connection failure between the interlayer connection conductor v2a and the signal terminal 26b can be reduced or prevented. More specifically, the insulator layer 16a (second insulator layer) has a Young's modulus at room temperature higher than the Young's modulus at room temperature of the insulator layer 17a (first insulator layer) (Condition 1). Further, the surface roughness of the portion Pa located in the insulator layer 16a (second insulator layer) within the inner peripheral surface of the through-hole is larger than the surface roughness of the portion Pb located in the insulator layer 17a (first insulator layer) within the inner peripheral surface of the through-hole (Condition 2). Thus, the interlayer connection conductor v2a adheres strongly to the hard insulator layer 16a. In other words, the interlayer connection conductor v2a is held in the insulator layer 16a due to the anchor effect. As a result, the interlayer connection conductor v2a is reduced or prevented from coming out of the through-hole when the multilayer body 12 is deformed or the like. Thus, with the circuit board 10, the occurrence of connection failure between the interlayer connection conductor v2a and the signal terminal 26b can be reduced or prevented. For the same reason as the interlayer connection conductor v2a, the occurrence of connection failure is also reduced or prevented in the interlayer connection conductors v2b, v4a, and v4b.

The substantiation of Condition 1 is as follows. First, the insulator layers 16a and 17a are taken out from the multilayer body 12 to make a specimen. The Young's modulus at room temperature of the specimen is measured while scraping only the insulator layer 16a from the specimen. If the Young's modulus at room temperature of the specimen decreases with the removal of the insulator layer 16a, the Young's modulus at room temperature of the insulator layer 16a is higher than the Young's modulus at room temperature of the insulator layer 17a.

The substantiation for Condition 2 is as follows. The circuit board 10 is cut to form a cross section shown in FIG. 2. The cross section is observed by SEM. At this time, the image of the inner peripheral surface of the through-hole (i.e., the surface formed by the insulator layer) is observed. The surface roughness is measured by tracing an image of the inner peripheral surface of the through-hole. The surface roughness in the present description is, for example, arithmetic surface roughness. By tracing the image of the inner peripheral surface of the through-hole, height information of each location is converted, and arithmetic mean roughness is calculated according to the definition of arithmetic mean roughness.

With the circuit board 10, the occurrence of connection failure between the interlayer connection conductor v2a and the signal terminal 26b can also be reduced or prevented due to the following reasons. More specifically, when viewed in the up-down direction (the Z-axis direction), the area of the upper end of the interlayer connection conductor v2a (the end in the positive direction of the Z-axis) is smaller than the area of the lower end of the interlayer connection conductor v2a (the end in the negative direction of the Z-axis). In such an interlayer connection conductor v2a, connection failure is likely to occur between the upper end of the interlayer connection conductor v2a, which has a small area when viewed in the up-down direction, and the signal terminal 26b.

Therefore, the lower main surface (negative main surface) of the insulator layer 16a (second insulator layer) is in contact with the upper main surface (positive main surface) of the insulator layer 17a (first insulator layer). In other words, the insulator layer 16a is located above the insulator layer 17a. Further, the insulator layer 16a (second insulator layer) has a Young's modulus at room temperature higher than the Young's modulus at room temperature of the insulator layer 17a (first insulator layer). Further, the surface roughness of the portion Pa located in the insulator layer 16a (second insulator layer) within the inner peripheral surface of the through-hole is larger than the surface roughness of the portion Pb located in the insulator layer 17a (first insulator layer) within the inner peripheral surface of the through-hole. Thus, the upper-end portion of the interlayer connection conductor v2a, in which connection failures are likely to occur, is brought into strong contact with the hard insulator layer 16a. In other words, the upper-end portion of the interlayer connection conductor v2a, in which connection failures are likely to occur, is held by the insulator layer 16a due to the anchor effect. As a result, positional deviation of the upper-end portion of the interlayer connection conductor v2a when the multilayer body 12 is deformed or the like is reduced or prevented. Thus, with the circuit board 10, the occurrence of connection failure between the interlayer connection conductor v2a and the signal terminal 26b can be reduced or prevented. For the same reason as the interlayer connection conductor v2a, the occurrence of connection failure is also reduced or prevented in the interlayer connection conductors v2b, v4a, and v4b.

In the circuit board 10, the surface roughness of the portion Pa located in the insulator layer 16a (second insulator layer) within the inner peripheral surface of the through-hole is larger than the surface roughness of the portion Pb located in the insulator layer 17a (first insulator layer) within the inner peripheral surface of the through-hole. In other words, the surface roughness of a portion of the interlayer connection conductor v2a is larger. Therefore, the portion where loss in the high-frequency signal in the interlayer connection conductor v2a is likely to occur is reduced. Thus, with the circuit board 10, the occurrence of loss in the high-frequency signal in the interlayer connection conductor v2a is reduced or prevented. For the same reason as the interlayer connection conductor v2a, the occurrence of loss in the high-frequency signal in the interlayer connection conductors v2b, v4a, and v4b is reduced or prevented.

With the circuit board 10, the occurrence of loss in the high-frequency signal in the interlayer connection conductor v2a is also reduced or prevented for the following reasons. More specifically, the thickness of the insulator layers 16a and 16b (second insulator layers) in the up-down direction (the Z-axis direction) is smaller than the thickness of the insulator layers 17a and 17b (first insulator layers) in the up-down direction (the Z-axis direction). Thus, since the area of the portion Pb is reduced, the portion where loss in the high-frequency signal in the interlayer connection conductor v2a is likely to occur is reduced. Therefore, with the circuit board 10, the occurrence of loss in the high-frequency signal in the interlayer connection conductor v2a is reduced or prevented. For the same reason as the interlayer connection conductor v2a, the occurrence of loss in the high-frequency signal in the interlayer connection conductors v2b, v4a, and v4b is reduced or prevented.

With the circuit board 10, the connector 50b is mounted on the signal terminal 26b. Therefore, when the mating connector is connected to the connector 50b, force is easily applied to the signal terminal 26b. Therefore, connection failure between the signal terminal 26b and the interlayer connection conductor v2a is likely to occur. Therefore, the insulator layers 16a and 17a, which are located near the signal terminal 26b, have the following structure. The insulator layer 16a (second insulator layer) has a Young's modulus at room temperature higher than the Young's modulus at room temperature of the insulator layer 17a (first insulator layer). The surface roughness of a portion Pa located in the insulator layer 16a (second insulator layer) within the inner peripheral surface of the through-hole is larger than the surface roughness of a portion Pb located in the insulator layer 17a (first insulator layer) within the inner peripheral surface of the through-hole. Thus, as described above, the occurrence of connection failure between the interlayer connection conductor v2a and the signal terminal 26b can be reduced or prevented.

In the circuit board 10, the materials of the insulator layers 16a and 16b are different from the materials of the insulator layers 17a and 17b. Thus, various materials of the insulator layers 16a and 16b can be combined with various materials of the insulator layers 17a and 17b. As a result, various electrical characteristics and various mechanical characteristics can be obtained in the circuit board 10.

In the circuit board 10, the insulator layers 16a and 16b (second insulator layers) have a Young's modulus at room temperature higher than the Young's modulus at room temperature of the insulator layers 17a and 17b (first insulator layers). The thickness of the insulator layers 16a and 16b (second insulator layers) in the up-down direction (the Z-axis direction) is smaller than the thickness of the insulator layers 17a and 17b (first insulator layers) in the up-down direction (the Z-axis direction). In other words, the hard insulator layers 16a and 16b are thinner than the soft insulator layers 17a and 17b. Thus, the multilayer body 12 can be easily bent.

### First Variation

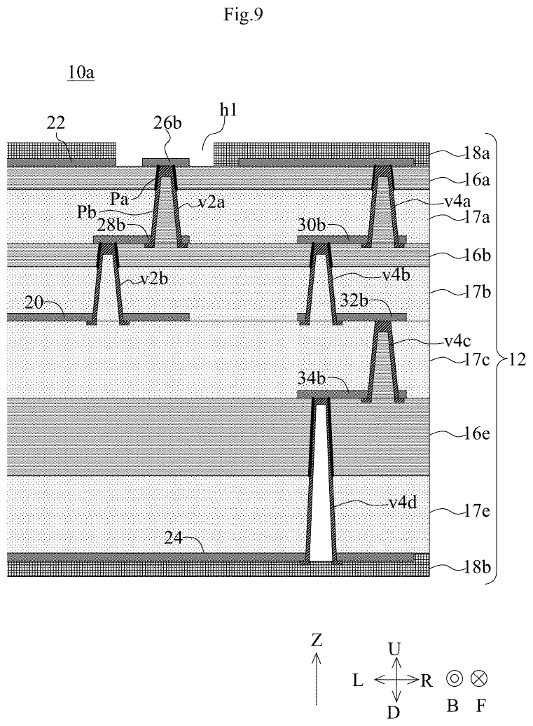

A circuit board 10a according to a first variation will be described below with reference to the drawings. FIG. 9 is a cross-sectional view of a right-end portion of the circuit board 10a.

The circuit board 10a differs from the circuit board 10 in that interlayer connection conductors v2a, v2b, and v4a to v4d are through-hole conductors and an insulator layer 16e is provided instead of the insulator layer 17d. The through-hole conductors are formed by plating the inner peripheral surface of through-holes. The interlayer connection conductor v2a passes through the connection conductor layer 28b in the up-down direction. The interlayer connection conductor v2b passes through the signal conductor layer 20 in the up-down direction. The interlayer connection conductor v4a passes through the connection conductor layer 30b in the up-down direction. The interlayer connection conductor v4b passes through the connection conductor layer 32b in the up-down direction. The interlayer connection conductor v4c passes through the connection conductor layer 34b in the up-down direction. The interlayer connection conductor v4d passes through the second ground conductor layer 24 in the up-down direction. Further, the interlayer connection conductor v4d passes through the insulator layers 16e and 17e in the up-down direction.

The insides of the interlayer connection conductors v2a, v2b, and v4a to v4c are filled with insulating materials. More specifically, a portion of the insulator layer 16b is filled inside the interlayer connection conductors v2a and v4a. A portion of the insulator layer 17c is filled inside the interlayer connection conductors v2b and v4b. A portion of the insulator layer 16e is filled inside the interlayer connection conductor v4c. However, the inside of the interlayer connection conductor v4d is not filled with insulating material. Since the other structures of the circuit board 10a are the same as those of the circuit board 10, the description thereof will be omitted. The circuit board 10a can achieve the same effects as the circuit board 10.

### Second Variation

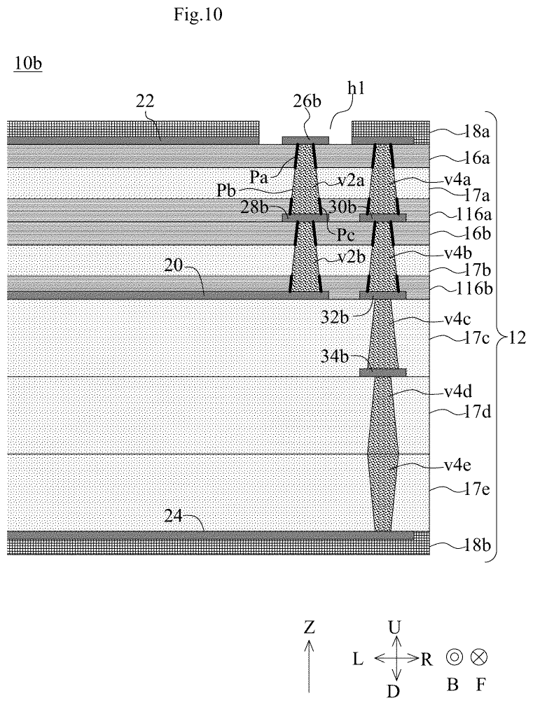

A circuit board 10b according to a second variation will be described below with reference to the drawings. FIG. 10 is a cross-sectional view of a right-end portion of the circuit board 10b.

The circuit board 10b differs from the circuit board 10 in that the multilayer body 12 includes insulator layers 116a and 116b (third insulator layer). More specifically, the insulator layers 116a and 116b (third insulator layers) have a Young's modulus at room temperature higher than the Young's modulus at room temperature of the insulator layers 17a and 17b (first insulator layers). The insulator layer 116a (third insulator layer) is located below (in the negative direction of the Z-axis) the insulator layer 17a (first insulator layer) and is in contact with the insulator layer 17a (first insulator layer). The insulator layer 116b (third insulator layer) is located below (in the negative direction of the Z-axis) the insulator layer 17b (first insulator layer) and is in contact with the insulator layer 17b (first insulator layer).

The connection conductor layers 28b and 30b (first conductor layers) are located on the lower main surface of the insulator layer 116a (third insulator layer), which is located below (in the negative direction of the Z-axis) the insulator layer 16a (second insulator layer). The signal conductor layer 20 and the connection conductor layer 32b (first conductor layer) are located on the lower main surface of the insulator layer 116b (third insulator layer), which is located below (in the negative direction of the Z-axis) the insulator layer 16b (second insulator layer).

The through-holes where the interlayer connection conductors v2a and v4a are provided pass through the insulator layer 116a (third insulator layer) in the up-down direction (the Z-axis direction). The surface roughness of a portion Pc located in the insulator layer 116a (third insulator layer) within the inner peripheral surface of the through-hole is larger than the surface roughness of a portion Pb located in the insulator layer 17a (first insulator layer) within the inner peripheral surface of the through-hole. The through-holes where the interlayer connection conductors v2b and v4b are provided pass through the insulator layer 116b (third insulator layer) in the up-down direction (the Z-axis direction). The surface roughness of a portion Pc located in the insulator layer 116b (third insulator layer) within the inner peripheral surface of the through-hole is larger than the surface roughness of a portion Pb located in the insulator layer 17b (first insulator layer) within the inner peripheral surface of the through-hole. Since the other structures of the circuit board 10b are the same as those of the circuit board 10, the description thereof will be omitted. The circuit board 10b can achieve the same effects as the circuit board 10.

With the circuit board 10b, the area where the interlayer connection conductor v2a is firmly held is larger. Thus, the occurrence of connection failure between the interlayer connection conductor v2a and the signal terminal 26b can be reduced or prevented.

Further, with the circuit board 10b, the occurrence of connection failure between the interlayer connection conductor v2a and the connection conductor layer 28b can be reduced or prevented. More specifically, the insulator layer 116a (third insulator layer) is located below (in the negative direction of the Z-axis) the insulator layer 17a (first insulator layer) and is in contact with the insulator layer 17a (first insulator layer). The surface roughness of the portion Pc located in the insulator layer 116a (third insulator layer) within the inner peripheral surface of the through-hole is larger than the surface roughness of the portion Pb located in the insulator layer 17a (first insulator layer) within the inner peripheral surface of the through-hole. Thus, the lower-end portion of the interlayer connection conductor v2a adheres strongly to the hard insulator layer 116a. In other words, the lower-end portion of the interlayer connection conductor v2a is held by the insulator layer 116a due to the anchor effect. As a result, positional deviation of the lower-end portion of the interlayer connection conductor v2a when the multilayer body 12 is deformed or the like is reduced or prevented. Thus, with the circuit board 10b, the occurrence of connection failure between the interlayer connection conductor v2a and the connection conductor layer 28b can be reduced or prevented. For the same reason as the interlayer connection conductor v2a, the occurrence of connection failure is also reduced or prevented in the interlayer connection conductors v2b, v4a, and v4b.

### Third Variation

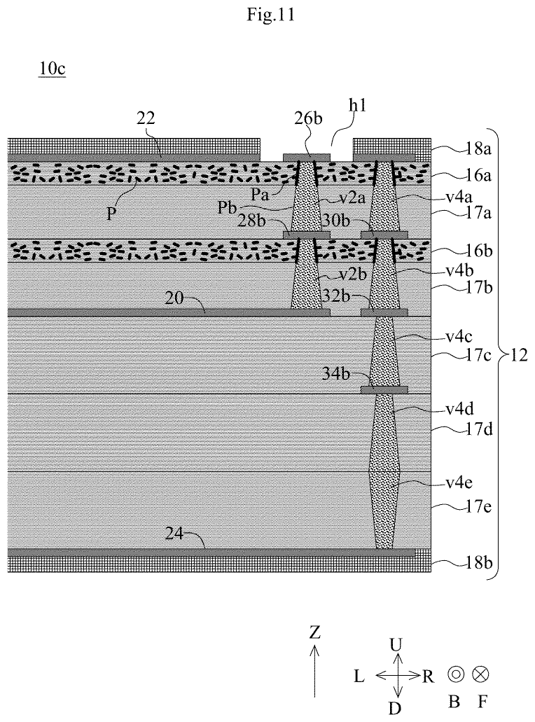

A circuit board 10c according to a third variation will be described below with reference to the drawings. FIG. 11 is a cross-sectional view of a right-end portion of the circuit board 10c.

The circuit board 10c differs from the circuit board 10 in the structure of the insulator layers 16a and 16b. More specifically, the insulator layers 16a and 16b (second insulator layers) have a structure in which a plurality of particles P are dispersed in a resin. The plurality of particles P each have a shape having a longitudinal direction and a transverse direction. The number of the plurality of particles P defining an angle of about 45 degrees or more between the longitudinal direction and the Z-axis is larger than the number of the plurality of particles P defining an angle smaller than about 45 degrees between the longitudinal direction and the Z-axis. A portion of the plurality of particles P is exposed on the inner peripheral surface of the through-holes in the insulator layers 16a and 16b (second insulator layer). Thus, the surface roughness of a portion Pa located in the insulator layer 16a within the inner peripheral surface of the through-hole is larger than the surface roughness of a portion Pb located in the insulator layer 17a within the inner peripheral surface of the through-hole. The surface roughness of a portion Pa located in the insulator layer 16b within the inner peripheral surface of the through-hole is larger than the surface roughness of a portion Pb located in the insulator layer 17b within the inner peripheral surface of the through-hole.

Here, the resin is, for example, a fluororesin. The material of the plurality of particles P is an inorganic material. The material of the plurality of particles P is, for example, boron nitride. Thus, the Young's modulus at room temperature of the plurality of particles P is larger than the Young's modulus at room temperature of the resin. Thus, the Young's modulus at room temperature of the insulator layers 16a and 16b is larger than the Young's modulus at room temperature of the insulator layers 17a to 17e. The dielectric constant of the plurality of particles P may be lower than the dielectric constant of the resin. Thus, the dielectric constant of the insulator layers 16a and 16b decreases.

In the circuit board 10c, the material of the insulator layers 17a to 17e is the same fluororesin as the material of the insulator layers 16a and 16b. The other structure of the circuit board 10c is the same as that of the circuit board 10. The circuit board 10c can achieve the same effects as the circuit board 10.

Further, in the circuit board 10c, the plurality of particles P each have a shape having a longitudinal direction and a transverse direction. The number of the plurality of particles P defining an angle of about 45 degrees or more between the longitudinal direction and the Z-axis is larger than the number of the plurality of particles P defining an angle smaller than about 45 degrees between the longitudinal direction and the Z-axis (Condition 3). Thus, the linear expansion coefficients of the insulator layers 16a and 16b in the front-back direction and the left-right direction become low.

Condition 3 is substantiated by the following procedure. First, a specimen is cut from the insulator layers 16a and 16b. By observing the specimen, the number of the plurality of particles P defining an angle of about 45 degrees or more between the longitudinal direction and the Z-axis and the number of the plurality of particles P defining an angle smaller than about 45 degrees between the longitudinal direction and the Z-axis are counted.

### Fourth Variation

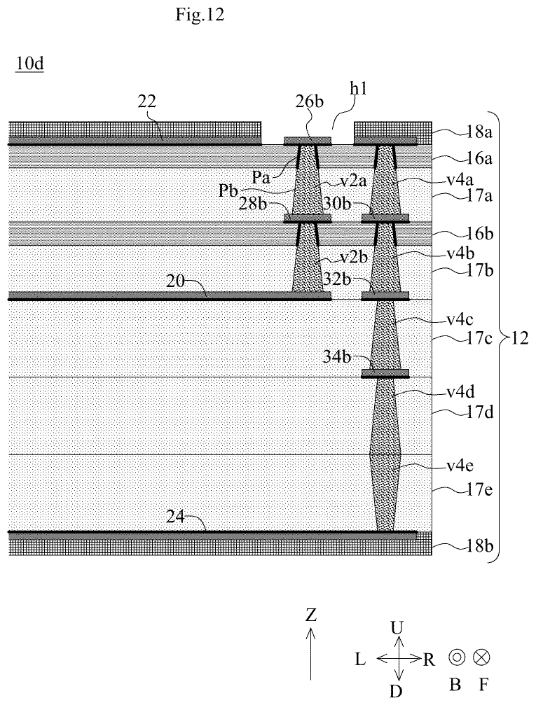

A circuit board 10d according to a fourth variation will be described below with reference to the drawings. FIG. 12 is a cross-sectional view of a right-end portion of the circuit board 10d.

In the circuit board 10d, the surface roughness of the upper main surface (positive main surface) of the connection conductor layers 28b and 30b (first conductor layers) is smaller than the surface roughness of the lower main surface (negative main surface) of the connection conductor layers 28b and 30b (first conductor layers). Thus, the connection conductor layers 28b and 30b are firmly fixed to the insulator layer 16b due to the anchor effect. The surface roughness of the lower main surface (negative main surface) of the first ground conductor layer 22 and the signal terminal 26b (second conductor layer) is larger than the surface roughness of the upper main surface (positive main surface) of the first ground conductor layer 22 and the signal terminal 26b (second conductor layer). Thus, the first ground conductor layer 22 and the signal terminal 26b are firmly fixed to the insulator layer 16a due to the anchor effect. Since the other structures of the circuit board 10d are the same as those of the circuit board 10, the description thereof will be omitted. The circuit board 10d can achieve the same effects as the circuit board 10.

In the circuit board 10d, the connection conductor layers 28b and 30b are firmly fixed to the insulator layer 16b due to the anchor effect. The first ground conductor layer 22 and the signal terminal 26b are firmly fixed to the insulator layer 16a due to the anchor effect. Therefore, the connection conductor layers 28b and 30b do not have to be chemically bonded to the insulator layer 16b. The first ground conductor layer 22 and signal terminal 26b do not have to be chemically bonded to the insulator layer 16a. Thus, the degree of freedom in material selection for insulator layers 16a and 16b is improved.

### Fifth Variation

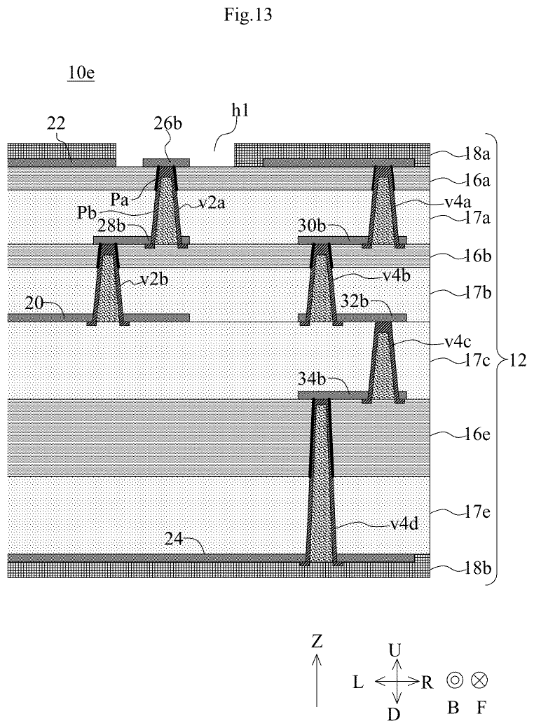

A circuit board 10e according to a fifth variation will be described below with reference to the drawings. FIG. 13 is a cross-sectional view of a right-end portion of the circuit board 10e.

The circuit board 10e differs from the circuit board 10a in that the insides of the interlayer connection conductors v2a, v2b, and v4a to v4d are filled with a conductive material. The conductive material is formed, for example, by sintering a conductive paste, which is a mixture of a resin and a metal powder. Since the other structures of the circuit board 10e are the same as those of the circuit board 10a, the description thereof will be omitted. The circuit board 10e can achieve the same effects as the circuit board 10a.

### Other Example Embodiments

The transmission lines according to the present invention are not limited to the circuit boards 10 and 10a to 10e, but can be modified within the scope of its gist. The configurations of the circuit boards 10 and 10a to 10e may be combined as desired.

A conductor layer may exist between the first insulator layer and the second insulator layer.

The interlayer connection conductors may pass through the first conductor layer or the second conductor layer in the Z-axis direction.

When viewed in the up-down direction, the area of the end of the interlayer connection conductor in the positive direction of the Z-axis may be larger than or equal to the area of the end of the interlayer connection conductor in the negative direction of the Z-axis.

The plurality of particles need not have a longitudinal direction and a transverse direction. In other words, the shape of the plurality of particles may be spherical.

The number of the plurality of particles defining an angle of about 45 degrees or more between the longitudinal direction and the Z-axis may be smaller than the number of the plurality of particles defining an angle smaller than about 45 degrees between the longitudinal direction and the Z-axis.

In the circuit board 10c, the resin of the insulator layers 16a and 16b may be different from the resin of the insulator layers 17a and 17b.

The thickness of the second insulator layer in the Z-axis direction may be larger than or equal to the thickness of the first insulator layer in the Z-axis direction.

The material of the first insulator layer and/or the second insulator layer may be a fluororesin.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A circuit board comprising:
a multilayer body including a plurality of insulator layers including a first insulator layer and a second insulator layer, the second insulator layer having a Young's modulus at room temperature higher than a Young's modulus at room temperature of the first insulator layer, the first and second insulator layers being laminated in a Z-axis direction, the plurality of insulator layers each including a negative main surface located in a negative direction of a Z-axis and a positive main surface located in a positive direction of the Z-axis, the negative main surface of the second insulator layer being in contact with the positive main surface of the first insulator layer;
an interlayer connection conductor provided inside a through-hole that passes through the first insulator layer and the second insulator layer in the Z-axis direction;
a first conductor layer that is located on the negative main surface of the insulator layer located farther in the negative direction of the Z-axis than the second insulator layer, and that is in contact with an end portion of the interlayer connection conductor in the negative direction of the Z-axis; and
a second conductor layer that is located on the positive main surface of the second insulator layer and that is in contact with an end portion of the interlayer connection conductor in the positive direction of the Z-axis;
wherein
a surface roughness of a portion located in the second insulator layer within an inner peripheral surface of the through-hole is larger than a surface roughness of a portion located in the first insulator layer within the inner peripheral surface of the through-hole; and
no conductor layer in contact with the interlayer connection conductor is provided between the first insulator layer and the second insulator layer.

2. The circuit board according to claim 1, wherein the first conductor layer is located on the negative main surface of the first insulator layer.

3. The circuit board according to claim 1, wherein
the plurality of insulator layers include a third insulator layer;
the third insulator layer has a Young's modulus at room temperature higher than the Young's modulus at room temperature of the first insulator layer, and is located farther in the negative direction of the Z-axis than the first insulator layer, and is in contact with the first insulator layer;
the through-hole passes through the third insulator layer in the Z-axis direction; and
the insulator layer located farther in the negative direction of the Z-axis than the second insulator layer is the third insulator layer.

4. The circuit board according to claim 3, wherein a surface roughness of a portion located in the third insulator layer within the inner peripheral surface of the through-hole is larger than the surface roughness of the portion located in the first insulator layer within the inner peripheral surface of the through-hole.

5. The circuit board according to claim 1, wherein no conductor layer is provided between the first insulator layer and the second insulator layer.

6. The circuit board according to claim 1, wherein the interlayer connection conductor does not pass through the first conductor layer and the second conductor layer in the Z-axis direction.

7. The circuit board according to claim 1, wherein when viewed in the Z-axis direction, an area of an end of the interlayer connection conductor in the positive direction of the Z-axis is smaller than an area of an end of the interlayer connection conductor in the negative direction of the Z-axis.

8. The circuit board according to claim 1, wherein the second insulator layer has a structure in which a plurality of particles are dispersed in a resin.

9. The circuit board according to claim 8, wherein the plurality of particles each have a shape having a longitudinal direction and a transverse direction.

10. The circuit board according to claim 9, wherein a number of the plurality of particles defining an angle of about 45 degrees or more between the longitudinal direction and the Z-axis is larger than a number of the plurality of particles defining an angle smaller than about 45 degrees between the longitudinal direction and the Z-axis.

11. The circuit board according to claim 8, wherein a portion of the plurality of particles is exposed on the inner peripheral surface of the through-hole of the second insulator layer.

12. The circuit board according to claim 1, wherein a surface roughness of a positive main surface of the first conductor layer is smaller than a surface roughness of a negative main surface of the first conductor layer, and a surface roughness of a negative main surface of the second conductor layer is larger than a surface roughness of a positive main surface of the second conductor layer.

13. The circuit board according to claim 1, wherein a surface roughness of a negative main surface of the first conductor layer is equal or substantially equal to a surface roughness of a positive main surface of the first conductor layer, and a surface roughness of a negative main surface of the second conductor layer is equal or substantially equal to a surface roughness of a positive main surface of the second conductor layer.

14. The circuit board according to claim 13, wherein a material of the first insulator layer and/or a material of the second insulator layer is a fluororesin.

15. The circuit board according to claim 1, wherein the multilayer body includes a first section and a second section, and the second section is bent, relative to the first section, in the Z-axis direction of the first section.

16. The circuit board according to claim 1, wherein a thickness of the second insulator layer in the Z-axis direction is smaller than a thickness of the first insulator layer in the Z-axis direction.

17. A method of producing a circuit board, comprising:
preparing a first insulator layer and a second insulator layer each including a negative main surface located in a negative direction of a Z-axis and a positive main surface located in a positive direction of the Z-axis, the second insulator layer having a Young's modulus at room temperature higher than a Young's modulus at room temperature of the first insulator layer, a second conductor layer being provided on the positive main surface of the second insulator layer;
after the preparing, laminating the first insulator layer and the second insulator layer so that the negative main surface of the second insulator layer in the Z-axis is in contact with the positive main surface of the first insulator layer;
after the laminating, radiating a laser beam from a space located in the negative direction of the first insulator layer and the second insulator layer to form a through-hole that passes through the first insulator layer and the second insulator layer in a Z-axis direction; and
after the radiating, forming an interlayer connection conductor inside the through-hole; wherein
in the radiating, the laser beam is radiated while an intensity of the laser beam is increased over time.

18. The method of producing a circuit board according to claim 17, further comprising, after the radiating, laminating a plurality of insulator layers including the first insulator layer and the second insulator layer.

19. The method of producing a circuit board according to claim 17, wherein in the radiating, the laser beam is radiated so that the through-hole does not pass through the second conductor layer in the Z-axis direction.
